(19) United States
(12) Patent Application Publication
(10) Pub. No.: US 2023/0132893 A1
(43) Pub. Date: May 4, 2023

(54) MASK LAYOUT CORRECTION METHODS BASED ON MACHINE LEARNING, AND MASK MANUFACTURING METHODS INCLUDING THE CORRECTION METHODS

(71) Applicant: Samsung Electronics Co., Ltd., Suwon-si (KR)

(72) Inventors: Mijin Kwon, Anyang-si (KR); Sangchul Yeo, Osan-si (KR)

(21) Appl. No.: 17/841,734

(22) Filed: Jun. 16, 2022

(30) Foreign Application Priority Data
Nov. 3, 2021 (KR) 10-2021-0149955

(51) Int. Cl. G03F 1/36; G06T 7/00; G03F 1/70; G06F 16/51

(52) U.S. Cl. CPC G03F 1/36; G06T 7/0004; G03F 1/70; G06F 16/51; G06T 2207/10061; G06T 2207/20081; G06T 2207/30148

(57) ABSTRACT

A reliable mask layout correction method capable of manufacturing a mask including a curvilinear pattern, and a mask manufacturing method including the correction method. The mask layout correction method based on machine learning may include: acquiring optical proximity correction (OPC)-ed layout images for masks including a curvilinear pattern, extracting mask contour images from scanning electron microscope (SEM) images for masks manufactured based on the OPC-ed layout images, performing machine learning using the OPC-ed layout images and the mask contour images to generate a conversion model, and correcting the OPC-ed layout images using the conversion model.

### CROSS-REFERENCE TO RELATED APPLICATION

This application is based on and claims priority under 35 U.S.C. § 119 to Korean Patent Application No. 10-2021-0149955, filed on Nov. 3, 2021, in the Korean Intellectual Property Office, the disclosure of which is incorporated by reference herein in its entirety.

### TECHNICAL FIELD

The present disclosure relates to mask manufacturing methods, and more particularly, to mask layout correction methods and a mask manufacturing methods that include the mask layout correction methods.

### BACKGROUND

In semiconductor processes, a photolithography process using a mask may be performed to form a pattern on a semiconductor substrate such as a wafer. A mask may be simply defined as a pattern transfer body in which a pattern shape of an opaque material is formed on a transparent base material. Briefly describing a mask manufacturing process, a required circuit is first designed, a layout for the circuit is designed, and then mask design data obtained through optical proximity correction (OPC) is transferred as mask tape-out (MTO) design data. Thereafter, mask data preparation (MDP) is performed based on the MTO design data, and a front end of line (FEOL), such as an exposure process, and a back end of line (BEOL), such as a defect inspection, are performed to manufacture a mask.

### SUMMARY

The present disclosure provides reliable mask layout correction methods (e.g., a more reliable mask layout correction method) that may be capable of manufacturing a mask that includes a curvilinear pattern, and mask manufacturing methods that include the mask layout correction methods.

According to some aspects of the inventive concepts, there may be provided a mask layout correction method including: acquiring optical proximity correction (OPC)-ed layout images for masks, each of the masks including a curvilinear pattern, extracting mask contour images from scanning electron microscope (SEM) images for masks manufactured based on the OPC-ed layout images, performing machine learning using the OPC-ed layout images and the mask contour images to generate a conversion model, and correcting the OPC-ed layout images using the conversion model.

According to some aspects of the inventive concepts, there is provided a mask layout correction method including: generating a database (DB) including optical proximity correction (OPC)-ed layout images for masks, each of the masks including a curvilinear pattern, extracting mask contour images from scanning electron microscope (SEM) images for masks manufactured based on the OPC-ed layout images, performing deep learning based on a generative adversarial network (GAN) using the OPC-ed layout images and the mask contour images to generate a conversion model, correcting the OPC-ed layout images using the conversion model, generating a new DB including the corrected OPC-ed layout images, performing mask rule check (MRC) on the corrected OPC-ed layout images, determining that there is not a defect in the performing of the MRC, and determining the corrected OPC-ed layout images to be final OPC-ed layout images.

According to some aspects of the inventive concepts, there is provided a mask manufacturing method including generating a database (DB) including optical proximity correction (OPC)-ed layout images for masks, each of the masks including a curvilinear pattern, extracting mask contour images from scanning electron microscope (SEM) images for masks manufactured based on the OPC-ed layout images, performing deep learning based on a generative adversarial network (GAN) using the OPC-ed layout images and the mask contour images to generate a conversion model, correcting the OPC-ed layout images using the conversion model to acquire final OPC-ed layout images, transferring the final OPC-ed layout images as mask tape-out (MTO) design data, preparing mask data based on the MTO design data, and exposing a substrate for a mask based on the mask data.

### BRIEF DESCRIPTION OF THE DRAWINGS

Some embodiments of the inventive concepts will be more clearly understood from the following detailed description taken in conjunction with the accompanying drawings in which:

FIG. 1 is a flowchart schematically illustrating a process of a mask layout correction method based on machine learning according to some embodiments of the inventive concepts;

FIG. 2A is a conceptual diagram illustrating a method of detecting a horizontal/rectilinear mask CD offset in a mask including a rectilinear pattern, and FIG. 2B is a conceptual diagram illustrating a problem in applying the method of detecting a horizontal/rectilinear mask CD offset to a mask including a curvilinear pattern;

FIGS. 3A to 3C are plan views illustrating an optical proximity corrected (OPC-ed) layout image, a mask contour image by a scanning electron microscope (SEM), and the two images together for comparison, respectively;

FIGS. 4A and 4B are conceptual diagrams schematically illustrating a deep learning process based on a generative adversarial network (GAN) algorithm used in the mask layout correction method based on machine learning of FIG. 1;

FIGS. 5A and 5B are conceptual diagrams illustrating a predictive model and a reverse model as conversion models obtained through deep learning using a GAN algorithm in the mask layout correction method based on machine learning of FIG. 1, respectively; and

FIG. 6 is a flowchart schematically illustrating a process of a mask manufacturing method including a mask layout correction method according to some embodiments of the inventive concepts.

### DETAILED DESCRIPTION OF THE EMBODIMENTS

Hereinafter, some embodiments of the inventive concept are described in detail with reference to the accompanying drawings. The same reference numerals are used for the same components in the drawings, and redundant descriptions thereof may be omitted herein in the interest of brevity.

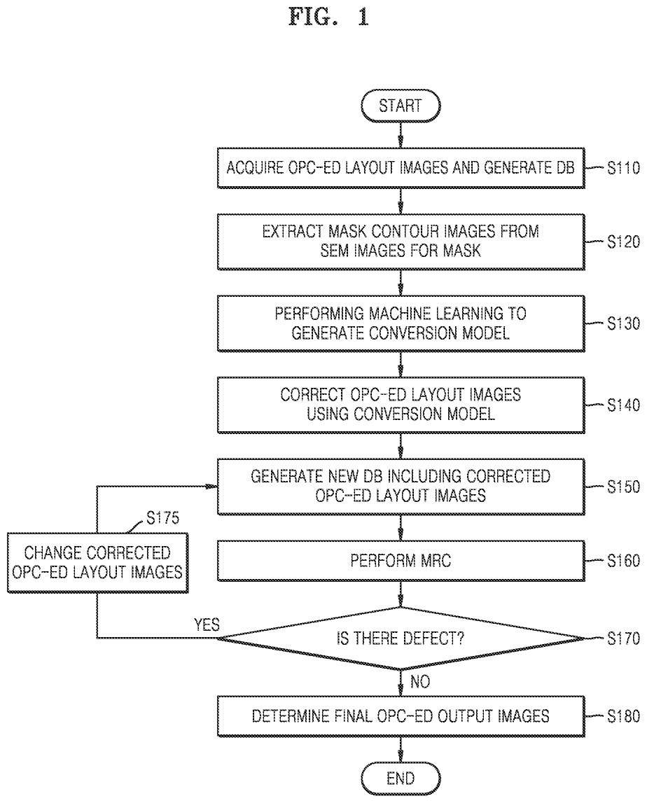

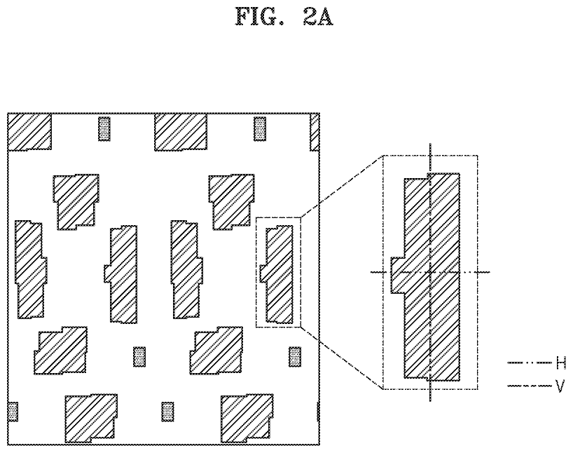

FIG. 1 is a flowchart schematically illustrating a process of a mask layout correction method based on machine learning according to some embodiments of the inventive concepts.

Referring to FIG. 1, first, in the mask layout correction method based on machine learning according to some embodiments (hereinafter, simply referred to as a ‘mask layout correction method’), OPC-ed layout images on which Optical Proximity Correction (OPC) has been performed may be acquired and a database (DB) may be generated (operation S110). The DB may include multiple OPCed layout images. In the mask layout correction method of some embodiments, the OPCed layout images may refer to layout images output through OPC with respect to masks including a curvilinear pattern.

In some embodiments, the pattern on a substrate such as a wafer may be formed by transferring a pattern on a mask onto the substrate through an exposure process. Accordingly, first, a layout for the pattern on the mask corresponding to the pattern on the substrate, that is, a mask layout, may be designed. For reference, in general, a shape of the pattern on the substrate may be different from a shape of the pattern on the mask due to the nature of the exposure process. In addition, because the pattern on the mask is reduced-projected and transferred onto the substrate, the pattern on the mask may have a larger size than the pattern on the substrate.

Moreover, as the pattern is refined, an optical proximity effect (OPE) due to the influence between neighboring patterns may occur during the exposure process. To overcome this, OPC may be performed, which may correct the mask layout and thereby suppress OPE occurrences. OPC may include generating an image or data of the corresponding pattern, generating an OPC model, and acquiring an image or data of a mask layout through simulation using the OPC model.

OPC is generally described as follows. OPC is largely classified according to two types: one is rule-based OPC, and the other is simulation-based or model-based OPC. The OPC in the mask layout correction method of some embodiments of the present inventive concepts may be, for example, model-based OPC. Model-based OPC may be advantageous in terms of time and cost, because there might not be a need to measure all of a large number of test patterns, and only a measurement result of representative patterns is used. In addition, OPC may include a method of adding sub-lithographic features called serifs on the corners of a pattern, as well as a modification of the mask layout, or a method of adding sub-resolution assist features (SRAFs) such as scattering bars.

For OPC, first, basic data for OPC may be prepared. Here, the basic data may include data on a shape of patterns of a sample, positions of the patterns, a type of measurement such as measurement of a space or line of a pattern, and/or a basic measurement value. In addition, the basic data may include information such as thickness, refractive index, and/or dielectric constant of a photoresist (PR), and/or may include a source map for a type of an illumination system. Of course, the basic data is not limited to the example data.

After preparing the basic data, an optical OPC model may be generated. The generating of the optical OPC model may include optimizing a defocus stand (DS) position, a best focus (BF) position, and/or the like in the exposure process. In addition, the generating of the optical OPC model may include creating an optical image considering a diffraction phenomenon of light or an optical state of an exposure facility itself. Of course, the generating of the optical OPC model is not limited to the above. For example, the generating of the optical OPC model may include a variety of content related to an optical phenomena in the exposure process.

After generating the optical OPC model, an OPC model for the PR may be generated. The generating of an OPC model for PR may include optimizing a threshold for PR. Here, the threshold for PR may refer to a threshold at which a chemical change occurs during the exposure process, and for example, the threshold may be given as an intensity of exposure light. The generating of an OPC model for PR may also include selecting an appropriate model form from several PR model forms.

The optical OPC model and the OPC model for PR may be generally collectively referred to as an OPC model. After the OPC model is generated, a simulation may be repeated using the OPC model. The simulation may be performed until a certain condition is satisfied. For example, a root mean square (RMS) for a CD error, an edge placement error (EPE), a reference number of repetitions, etc. may be used as a repetition condition of the simulation. In the mask layout correction method of some embodiments, OPC-ed layout images or data may be acquired through simulation using the OPC model. The OPC-ed layout images may be transmitted, as mask tape-out (MTO) design data, to a mask manufacturing team for subsequent mask manufacturing.

After acquiring the OPC-ed layout images and generating the DB, mask contour images may be extracted from scanning electron microscope (SEM) images of the mask (operation S120). Here, the mask may be an actual mask manufactured using the previously OPC-ed layout images. In other words, masks may be manufactured based on the OPC-ed layout images, the manufactured masks may be imaged using an SEM to acquire SEM images, and mask contour images may be extracted from the SEM images.

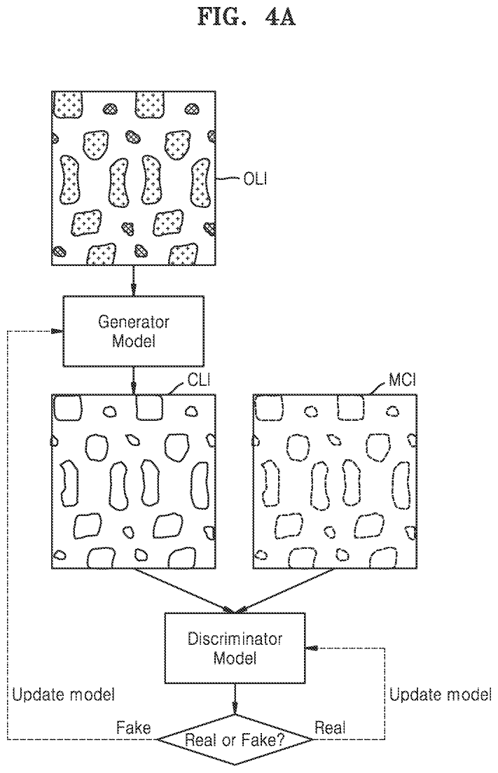

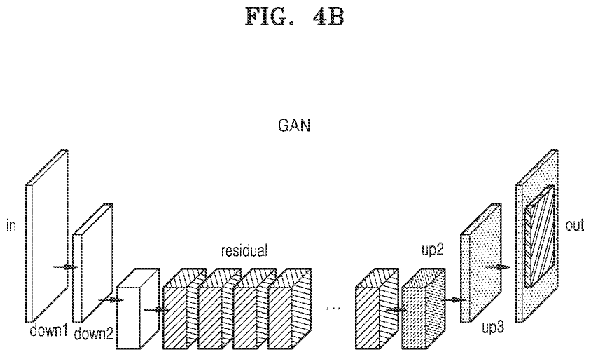

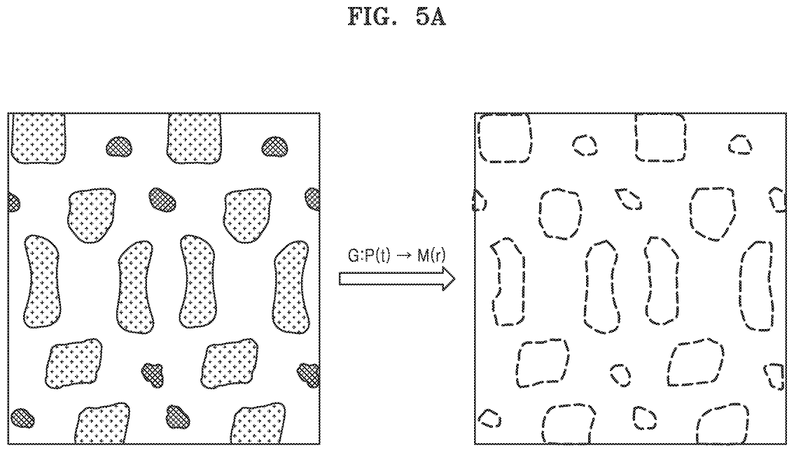

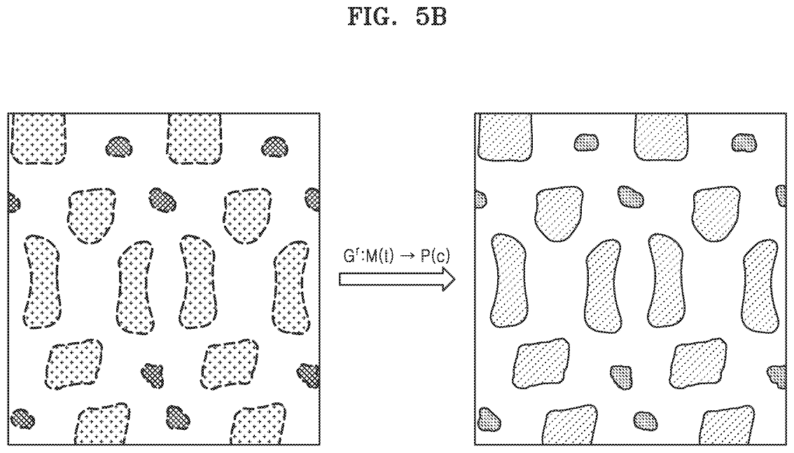

Subsequently, machine learning may be performed using the OPC-ed layout images and mask contour images, and a conversion model is generated (operation S130). Here, the machine learning may be deep learning. For example, in the mask layout correction method of some embodiments, machine learning may be deep learning based on a generative adversarial network (GAN) algorithm. Deep learning based on the GAN algorithm is described in greater detail herein with reference to FIGS. 4A to 5B.

After the conversion model is generated, the OPC-ed layout images may be corrected using the conversion model (operation S140). Here, the conversion model may include a predictive model and a reverse model, and correction of the OPC-ed layout images may be performed through the reverse model. The conversion model is described in greater detail herein with reference to FIGS. 5A and 5B.

After the OPC-ed layout images are corrected, a new DB including the corrected OPC-ed layout images may be generated (operation S150). In addition, because the new DB is only a set of corrected OPC-ed layout images, correcting the OPC-ed layout images (operation S140) and generating a new DB (operation S150) may be treated as one operation according to some embodiments.

Thereafter, mask rule check (MRC) may be performed (operation S160). MRC may be performed on the corrected OPC-ed layout images in the new DB. Here, MRC may refer to a check for restrictions on a width or an interval at which a pattern may be maintained when a mask is manufactured. For example, when a mask is manufactured, there may be restrictions in that the width of the pattern cannot be less than a set minimum width or the interval between the patterns cannot be less than a set minimum interval. Accordingly, performing MRC may refer to a process of checking whether the above restrictions are observed with respect to the mask layout.

After the MRC is performed, it may be determined whether there is a defect (operation S170). In other words, it may be determined whether there are items that violate the above restrictions in the corrected OPC-ed layout images from an MRC execution result. If there is a defect (Yes branch from operation S170), the corrected OPC-ed layout images may be changed to satisfy the above restrictions (operation S175). For example, the width of the patterns or the interval between the patterns may be changed to satisfy the above restrictions. Thereafter, the process may proceed to an operation of generating a new DB (operation S150).

Otherwise, if there is no defect (No branch from operation S170), the corrected OPC-ed layout images may be determined as final OPC-ed layout images (operation S180). The final OPC-ed layout image may be transferred, as MTO design data, to the mask manufacturing team for subsequent mask manufacturing.

In the mask layout correction method of some embodiments, mask contour images may be extracted from SEM images for an actual mask, and a conversion model may be generated through deep learning based on a GAN algorithm using the OPC-ed layout images and mask contour images. In addition, by correcting the OPC-ed layout images using the conversion model, optimal OPC-ed layout images for masks including a curvilinear pattern may be generated. Therefore, in the mask layout correction method of some embodiments, masks including corresponding a curvilinear pattern may be more precisely manufactured with high or higher reliability, based on the optimal OPC-ed layout images.

In the mask layout correction method of some embodiments, an offset for the curvilinear hole pattern, a pattern shift, and a distance between the patterns, which could not be checked in existing mask layout correction methods, may be checked at once. In addition, an optimal mask may be manufactured in an intended shape in OPC, thereby increasing an accuracy of patterning and increasing a possibility of forming patterns that were not able to be obtained previously. Furthermore, an exact mask manufacturing situation for weak points in patterning, such as corner rounding and corner to corner space, which could not be checked due to limitations in mask manufacturing, may be recognized. Accordingly, more accurate OPC modeling may be performed by reducing offset factors that reduce accuracy during OPC modeling.

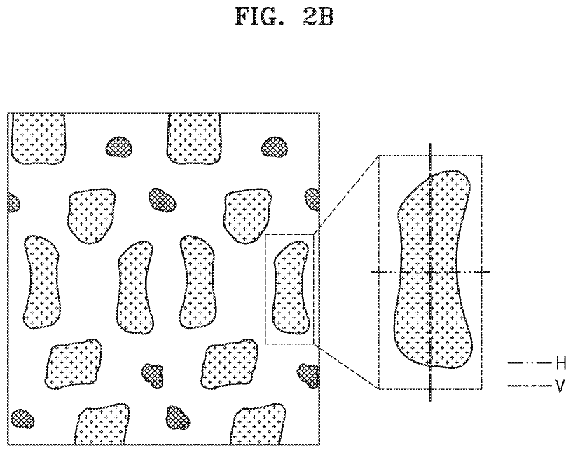

For reference, in existing mask layout correction methods, a CD of the pattern on the mask (hereinafter referred to as ‘mask CD’) may be measured in a horizontal/vertical direction to detect an offset, and then the OPC-ed layout image may be corrected by as much as the offset. Such an existing mask layout correction method is an effective mask layout correction method to some extent with respect to a mask including only a rectilinear pattern, and may help in manufacturing a reliable mask. However, application of such existing mask layout correction methods to a mask including a curvilinear pattern may cause problems as described hereinafter. A method of detecting an offset in a vertical (horizontal/vertical) direction in existing mask layout correction methods, and problems related to application to a mask including a curvilinear pattern, are described in greater detail in the description of FIGS. 2A and 2B below.

Hereinafter, the correction of the mask layout and the correction of the OPC-ed layout image may substantially mean the same. In addition, because the OPC-ed layout image is finally used as E-beam data for manufacturing a mask, the correction of the OPC-ed layout image has substantially the same meaning as correction or sizing of E-beam data.

FIG. 2A is a conceptual diagram illustrating a method of detecting a horizontal/rectilinear mask CD offset in a mask including a rectilinear pattern, and FIG. 2B is a conceptual diagram illustrating a problem in applying a method of detecting a horizontal/rectilinear mask CD offset in a mask including a curvilinear pattern.

Referring to FIG. 2A, in the case of an existing mask layout correction method for a mask that includes only rectilinear patterns, a reliable mask may be manufactured by detecting a horizontal/rectilinear mask CD offset and correcting the mask layout by as much as the offset or adjusting E-beam data. That is, in the existing mask layout correction method, the horizontal/rectilinear mask CD offset value may be measured at the center of the pattern, and the measured offset value may be reflected in the horizontal/vertical direction. The center of the pattern of FIG. 2A is indicated through the dashed-double dotted lines H and V. For reference, the offset value may be obtained by comparing a CD of the OPC-ed layout image with the mask CD measured with a measurement device. In addition, in the existing mask layout correction method, a mask CD offset value is detected for one anchor pattern and reflected in all patterns. Here, the anchor pattern may refer to a pattern representing patterns in the mask in shape and position.

Referring to FIG. 2B, in the case of a mask including curvilinear patterns, applying the method of detecting the horizontal/rectilinear mask CD offset, as it is, may be problematic due to the characteristics of the curvilinear pattern. In some embodiments, in the recent manufacturing of masks including increasingly smaller patterns, more accurate targeting and securing of margins may be required, so that a method of generating OPC patterns of a curvilinear pattern type with a high degree of freedom may be increasingly important and desirable over existing methods of generating OPC patterns only in a rectilinear pattern type. In particular, in masks including small contacts, various types of patterns, rather than simple line and space (L/S) patterns, may be desired. However, a mask that includes curvilinear patterns (hereinafter referred to as a ‘curvilinear mask’) manufactured thus far has been manufactured in the existing manner without an accurate definition of the mask CD of the curvilinear pattern, and thus, the reliability of mask manufacturing has been lowered. In other words, when a curvilinear mask is manufactured by detecting and reflecting the horizontal/rectilinear mask CD offset in the same manner as that in the method for a mask including only rectilinear patterns (hereinafter, referred to as a ‘rectilinear mask), the curvilinear mask may not be manufactured as intended, nor may it serve the purpose of a curvilinear mask to improve patterning.

As described above, in existing mask manufacturing methods, an offset between the CD of the OPC-ed layout image or the CD of the E-beam data and the mask CD for an actual mask, that is, the mask CD offset may be detected in the horizontal/vertical direction, and thereafter, the OPC-ed layout image may be corrected by as much as the offset value or the E-beam data may be adjusted. However, this method may be problematic because it may represent only the mask CD for a partial section of the curvilinear pattern. In addition, in the case of the existing method, shifting of a pattern, distortion of a pattern, or a targeting value of an end region of a pattern cannot be detected, and thus, there may be a high possibility that an offset or pattern shifting may still occur in the mask manufacturing process, and this may bring about results different from an OPC-ed layout image of a target or E-beam data of the target. In particular, because the mask CD offset of a single anchor pattern cannot represent the mask CD offset of all patterns due to the characteristics of the curvilinear mask, distortion of the patterns in the curvilinear mask may be highly likely, or even inevitable, even when the OPC-ed layout image or E-beam data may be corrected or updated based on a mask CD offset of the anchor pattern.

In contrast, in the mask layout correction methods of the present disclosure, a conversion model may be generated through machine learning, for example, deep learning based on a GAN algorithm, using an OPC-ed layout image and a corresponding mask contour image as a pair, and the OPC-ed layout image may be corrected through the conversion model to generate optimal E-beam data. Accordingly, the mask layout correction methods of the present disclosure may enable a reliable curvilinear mask with minimal occurrence of pattern distortion to be manufactured.

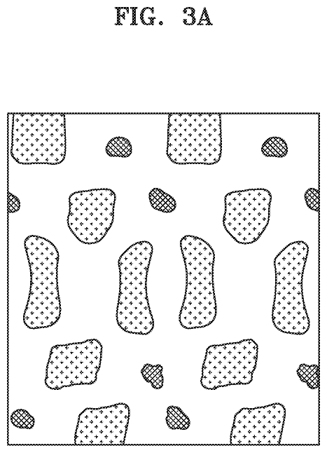

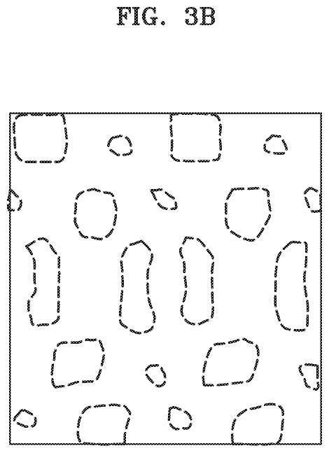

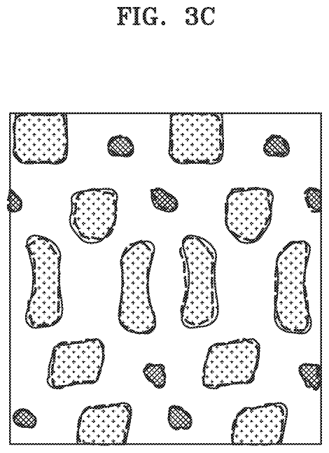

FIGS. 3A to 3C are plan views illustrating an OPC-ed layout image, a mask contour image by an SEM, and the two images together for comparison, respectively.

Referring to FIGS. 3A to 3C, FIG. 3A shows an OPC-ed layout image with respect to a mask including a curvilinear pattern. In addition, FIG. 3B shows a mask contour image extracted from an SEM image acquired by imaging a mask manufactured based on the OPC-ed layout image of FIG. 3A with an SEM. However, FIG. 3C shows the OPC-ed layout image of FIG. 3A and the mask contour image of FIG. 3B together in an overlapping manner for comparison.

When the OPC-ed layout image and corresponding E-beam data are accurately generated, the mask contour image of the pattern on the mask actually manufactured by the E-beam data may nearly or exactly match the OPC-ed layout image. However, as shown in FIG. 3C, there may be a difference between the mask contour image of the actual mask and the OPC-ed layout image. Such a difference may be caused in the process of manufacturing a mask based on the E-beam data, but it may not be easy to accurately find and remove or resolve the causes. Accordingly, as in the existing mask layout correction method described above, the mask CD offset may be detected, and the OPC-ed layout image may be corrected by as much as a corresponding offset to adjust the E-beam data. However, as described above, the existing mask layout correction method may be effective to a certain extent on a rectilinear mask, but applying the existing mask layout correction method to a curvilinear mask may be problematic.

In addition, in curvilinear mask manufacturing, in order to check whether the curvilinear pattern is properly implemented on the mask, it may be necessary to check an EPE for the contour of the pattern overall, in addition to measurement of a mask CD for only one gauge. Here, the gauge may refer to the coordinates and direction of an anchor pattern. In addition, in order for a curvilinear pattern with a higher degree of freedom to be properly implemented on a mask, EPE information on many points in the contour of the pattern may be desired. Therefore, it may be necessary to first extract contour information on the pattern implemented in the actual mask from the images of the mask CD measured by the SEM. Thereafter, by pairing the OPC-ed layout image set of a target with the contour image set of the pattern on the actually manufactured mask, that is, the mask contour image set, a difference between the two images made during mask manufacturing may be checked.

Moreover, in the mask layout correction methods of the present disclosure, in addition to the checking of the difference between the two images made during the manufacturing of the curvilinear mask, a conversion model may be generated by performing machine learning, e.g., deep learning based on a GAN algorithm, using the OPC-ed layout image and the mask contour image set, and the OPC-ed layout image may be corrected using the conversion model, thereby manufacturing a more reliable mask. Hereinafter, deep learning based on the GAN algorithm is described in detail with reference to FIGS. 4A and 4B.

FIGS. 4A and 4B are conceptual diagrams schematically illustrating a deep learning process based on a GAN algorithm used in the mask layout correction method based on machine learning of FIG. 1, in which FIG. 4A shows a general process of generating a conversion model using a GAN algorithm and FIG. 4B shows a process of applying CNN to a generator of the GAN.

Referring to FIG. 4A, the GAN algorithm may include a deep learning-based generative algorithm, and may include two sub-models. That is, the GAN algorithm may include a generator model and a discriminator model. The generator model may correspond to a conversion model or a predictive model in the mask layout correction methods of the present disclosure. The generator model generates new examples, and the discriminator model determines whether the generated examples are real data or fake data generated by the generator model.

For example, in relation to the mask layout correction method of the present embodiment, the generator model converts the input OPC-ed layout image to generate a converted layout image. The discriminator model receives the converted layout image and the mask contour image of the actual mask. In addition, the discriminator model compares the converted layout image with the mask contour image to determine whether the converted layout image is a real mask contour image or a fake mask contour image generated by the generator model.

In some embodiments, as seen in FIG. 4A, when the OPC-ed layout image (OLI) for a curvilinear mask is input to the generator model, the generator model generates a converted layout image (CLI). In addition, the CLI and a mask contour image (MCI) of the actual mask are input to the discriminator model. The discriminator model determines whether the CLI is the same as the MCI. For example, the discriminator model determines whether the CLI is a real MCI or a fake different from the MCI. Thereafter, the generator model and the discriminator model are continuously updated according to a determination result. By repeating this process over and over again, when the generator model reaches a level at which the discriminator model may no longer distinguish between the CLI and the MCI, training is finished, and a generator model at this time is adopted as a final generative model or a conversion model. In addition, the discriminator model may be discarded when the training is finished.

To better understand the operation of the GAN algorithm, consider that a producer model is akin to a counterfeiter and the discriminator model akin to a police officer or investigator. The job of the counterfeiter is to generate fake money that is indistinguishable from real money, and the job of the police officer is to distinguish between real money and fake money. Thus, the counterfeiter and the police officer may be considered to be in competition with each other, and from a game theory point of view, they are adversarial, with the effect of playing a zero-sum game. In other words, if the police officer successfully distinguishes between fake money and real money, the police officer does not need to update parameters for distinction. In addition, the counterfeiter has to update one or more parameters for forgery. Conversely, if the counterfeiter successfully generates fake money so that the police officer cannot distinguish between fake money and real money, the counterfeiter does not need to update the parameters for forgery. In contrast, the police officer has to update one or more parameters for distinction. If this process is repeated over and over again, the forgery may reach a level at which the police officer may no longer distinguish the forgery and/or be able to update the parameters for distinction, and the forgery method may become a final generative model or a conversion model.

Referring to FIG. 4B, in deep learning based on the GAN algorithm, in order for the generator model to generate a more accurate image, it may be necessary to accurately extract features from input images. In order to extract such features, a convolution process as shown in FIG. 4B may be used. The convolution process may be performed using a convolution filter and may include a downsampling process and an upsampling process. In addition, residual learning may be included between the downsampling and upsampling processes for more accurate learning. In the mask layout correction methods of the present disclosure, residual learning may be included in order to consider an optical effect of a surrounding region. Furthermore, upsampling may be performed after additional residual learning with the downsampled image once more, and then upsampling may be performed in combination with the residual learned image.

In FIG. 4B, in the final upsampled image, a large square portion may correspond to an image including peripheral regions, and an inner narrow square portion may correspond to an image of a central region. In general, an image including surrounding regions may include many errors. Accordingly, in the mask layout correction methods of the present disclosure, a generator model, that is, a conversion model, may be generated using the image of the central region.

In the mask layout correction method of the present embodiment, the GAN algorithm may be a cycle GAN algorithm. Accordingly, the conversion model generated through deep learning based on the GAN algorithm may include two models. For example, the conversion model may include a predictive model and a reverse model. Here, in simple terms, the cycle GAN algorithm may refer to executing the GAN algorithm in the form of a cycle by making an output image with an input image, and then inputting the output image again to obtain an input image. Hereinafter, the predictive model and the reverse model obtained through the cycle GAN algorithm are described in more detail with reference to FIGS. 5A and 5B.

FIGS. 5A and 5B are conceptual diagrams illustrating a predictive model and a reverse model as transformation models, respectively, which may be obtained through deep learning using a GAN algorithm in a mask layout correction method based on machine learning of FIG. 1.

Referring to FIG. 5A, the predictive model may be substantially the same as the generator model described above with reference to FIG. 4A. Accordingly, when the OPC-ed layout image is input to the generator model, a mask contour image corresponding thereto may be output. For example, as shown in FIG. 5A, when the OPC-ed layout image on the left is input to the predictive model, the predictive model may generate a mask contour image on the right.

For example, when the conversion model, e.g., the predictive model, that is generated through deep learning based on the GAN algorithm is very accurate, if an OPC-ed layout image is the OPC-ed layout image of FIG. 3A, a mask contour image generated by the predictive model may be substantially the same as a mask contour image of FIG. 3B.

In FIG. 5A, the formula of G:P(t)→M(r) may mean that, when the OPC-ed layout image (P(t)) is input to the predictive model G, the predictive model G may generate a corresponding mask contour image M(r). In P(t), t is an abbreviation for target, which may mean that the OPC-ed layout image corresponds to a layout image of a target mask to be implemented. Also, in M(r), r is an abbreviation of real, which may mean that the mask contour image generated by the predictive model G corresponds to a mask contour image of a real mask. After all, it means that, when the OPC-ed layout image of FIG. 3A is a layout image of the target mask, if the OPC-ed layout image P(t) of FIG. 3A is input to the predictive model G, the mask contour image M(r) of the actual mask of FIG. 3B may be generated.

As described with reference to FIGS. 3A to 3C, due to a cause during the mask manufacturing process, the OPC-ed layout image may be different from the mask contour image M(r) of the actually manufactured mask. Therefore, in order to accurately implement the layout image of the target mask on the mask, it may be necessary to correct the OPC-ed layout image. To this end, a reverse model G^{r}, which is described below with reference to FIG. 5B, may be used.

Referring to FIG. 5B, the reverse model G^{r} may have a concept opposite to that of the predictive model. For example, when an OPC-ed layout image is input to the predictive model, the predictive model may generate a mask contour image, whereas, when a mask contour image is input to the reverse model G^{r}, the reverse model G^{r} may generate an OPC-ed layout image.

For example, as shown in FIG. 5B, when the mask contour image on the left is input to the reverse model G^{r}, the reverse model G^{r} may generate the OPC-ed layout image on the right. Assuming that the left side is a mask contour image of a target mask, when a corresponding mask contour image is input to the reverse model G^{r}, the reverse model G^{r} may generate a corresponding OPC-ed layout image on the right. In addition, the OPC-ed layout image generated in this manner may correspond to an OPC-ed layout image obtained by correcting the OPC-ed layout image initially generated for manufacturing the target mask as discussed above.

In FIG. 5B, the formula of G^{r}:M(t)→P(c) may mean that, when a mask contour image M(t)) is input to the reverse model G^{r}, the reverse model G^{r} may generate a corresponding OPC-ed layout image P(c). In M(t), t is an abbreviation for a target, which may mean a mask contour image of a target mask. In addition, in P(c), c is an abbreviation for correction, which may mean that the OPC-ed layout image generated by the reverse model G^{r} corresponds to the corrected OPC-ed layout image for manufacturing a target mask.

As a result, it can be seen that the OPC-ed layout image of FIG. 3A may be corrected with the OPC-ed layout image on the right side of FIG. 5B. In addition, when the OPC-ed layout image (P(c)) on the right side of FIG. 5B is input to the predictive model (G), the predictive model (G) may generate the mask contour image (M(t)) of the target mask, which may be considered that the layout image of the target mask is accurately implemented on the actual mask.

In the mask layout correction methods of the present disclosure, a conversion model, e.g., a reverse model, may be generated through deep learning based on the GAN algorithm, and the OPC-ed layout image may be corrected using the reverse model. Accordingly, a target mask may be more accurately manufactured.

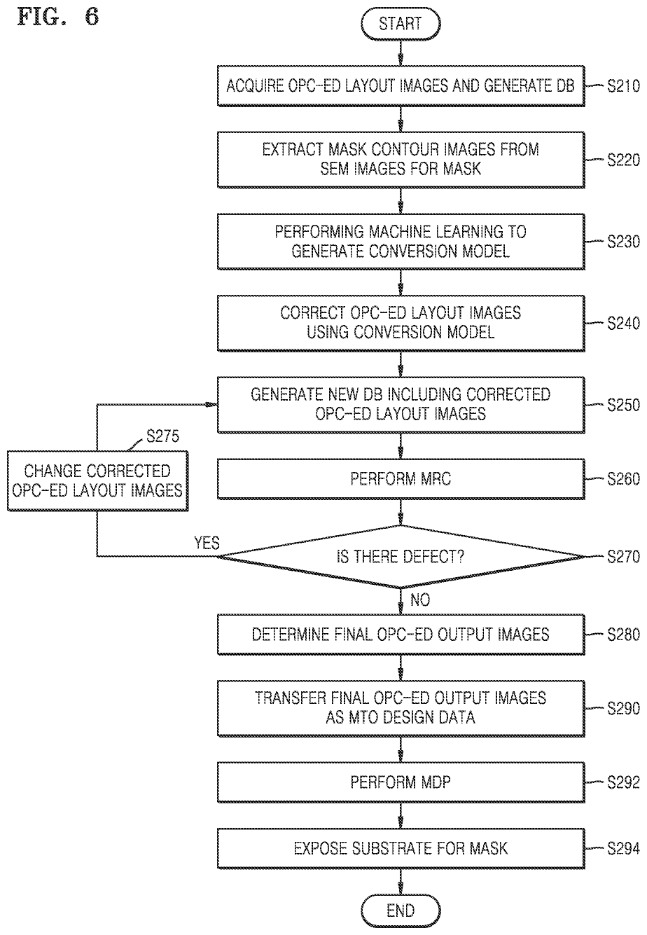

FIG. 6 is a flowchart schematically illustrating a process of a mask manufacturing method including a mask layout correction method according to some embodiments of the inventive concepts. The descriptions already given with reference to FIGS. 1 to 5B are briefly given or omitted.

Referring to FIG. 6, the mask manufacturing method including the mask layout correction method of the present embodiment (hereinafter, simply referred to as a ‘mask manufacturing method’) includes an operation of acquiring OPC-ed layout images and generating a DB (operation S210) to an operation of determining a final OPC-ed layout image (operation S280), which are sequentially performed. The operation of acquiring of the OPC-ed layout images and generating the DB (operation S210) and determining the final OPC-ed layout image (operation S280) may be the same as in the description of the mask layout correction method of FIG. 1.

Thereafter, the final OPC-ed layout image may be transferred as MTO design data to a mask manufacturing team (operation S290). In general, MTO may refer to requesting mask manufacturing by providing final mask data acquired through the OPC method to the mask manufacturing team. Accordingly, the MTO design data may eventually be substantially the same as data for the final OPC-ed layout image acquired through the mask layout correction method. The MTO design data may have a graphic data format used in electronic design automation (EDA) software or the like. For example, the MTO design data may have a data format such as Graphic Data System II (GDS2) and Open Artwork System Interchange Standard (OASIS).

Thereafter, mask data preparation (MDP) is performed (operation S292). The MDP may include, for example, i) format conversion, called fracturing, ii) augmentation of barcodes for mechanical reading, standard mask patterns for inspection, job deck, etc., and iii) automatic and manual verification. Here, the job deck may refer to generating a text file related to a series of instructions, such as arrangement information of multiple mask files, a reference dose, and an exposure speed or method.

In addition, format conversion, e.g., fracturing, may refer to a process of fracturing the MTO design data for each region and changing the MTO design data to a format for an electron beam exposure machine. The fracturing may include data manipulation such as scaling, sizing data, rotating data, pattern reflection, color inversion, and/or the like. During the conversion process through fracturing, data regarding numerous systematic errors that may occur anywhere during a transfer process from design data to an image on the wafer may be corrected. A data correction process for the systematic errors may be called mask process correction (MPC), and may include, for example, line width adjustment called CD adjustment and an operation to increase pattern arrangement precision. Therefore, fracturing may contribute to improving the quality of a final mask and may also be a process performed prior to MPC. Here, the systematic errors may be caused by distortion occurring in an exposure process, a mask development and etching process, and a wafer imaging process.

Moreover, the MDP may include the MPC. As described above, the MPC refers to a process of correcting an error occurring during an exposure process, e.g., a systematic error. Here, the exposure process may be a concept generally including electron beam writing, developing, etching, and baking. In addition, data processing may be performed prior to the exposure process. Data processing is a kind of preprocessing process for mask data, and may include grammar check for the mask data, prediction of exposure time, and/or the like. Through the MDP, E-beam data for exposing a substrate for a mask may be generated.

After the MDP, the substrate for a mask is exposed using the mask data, e.g., the E-beam data (operation S294). Here, exposure may refer to, for example, E-beam writing. Here, the E-beam writing may be performed by, for example, a gray writing method using a multi-beam mask writer (MBMW). In addition, the E-beam writing may also be performed using a variable shape beam (VSB) exposure machine.

After the MDP operation, a process of converting the E-beam data into pixel data may be performed before an exposure process. The pixel data may be data directly used for actual exposure, and may include data regarding a shape to be exposed and data regarding a dose of an E-beam assigned thereto. Here, the data regarding a shape may include bit-map data converted from shape data, which is vector data, through rasterization or the like.

After the exposure process, a series of processes may be performed to complete the mask. The series of processes may include, for example, development, etching, and/or cleaning. In addition, the series of processes for manufacturing the mask may include a measurement process, a defect inspection process, or a defect repair process. In addition, a pellicle application process may be included. Here, the pellicle application process may refer to a process of attaching a pellicle to the mask surface to protect the mask surface from subsequent contamination in the delivery of the mask and during a useful life of the mask when it is determined that there are no contaminating particles or chemical stains through the final cleaning and inspection.

The mask manufacturing methods of the present disclosure may include the mask layout correction method of FIG. 1 described above. Accordingly, optimal OPC-ed layout images for masks including a curvilinear pattern may be generated, and target masks including a corresponding curvilinear pattern may be more accurately manufactured with high or higher reliability based on the optimal OPC-ed layout images.

While some inventive concepts have been particularly shown and described with reference to some examples of embodiments thereof, it will be understood that various changes in form and details may be made therein without departing from the scope of the following claims.

What is claimed is:

1. A mask layout correction method, comprising:
acquiring optical proximity correction (OPC)-ed layout images for masks, each of the masks including a curvilinear pattern;
extracting mask contour images from scanning electron microscope (SEM) images of masks manufactured based on the OPC-ed layout images;
performing machine learning using the OPC-ed layout images and the mask contour images to generate a conversion model; and
correcting the OPC-ed layout images using the conversion model.

2. The mask layout correction method of claim 1, wherein the machine learning includes deep learning based on a generative adversarial network (GAN) algorithm.

3. The mask layout correction method of claim 2, wherein the conversion model includes a predictive model configured to convert the OPC-ed layout image into a corresponding mask contour image and a reverse model configured to convert the mask contour image into a corresponding OPC-ed layout image, and
wherein, in the correcting of the OPC-ed layout images, the OPC-ed layout images are corrected using the reverse model.

4. The mask layout correction method of claim 3, wherein, in the correcting of the OPC-ed layout images, the OPC-ed layout images are corrected into OPC-ed layout images corresponding to mask contour images of a target using the reverse model.

5. The mask layout correction method of claim 1, wherein, the acquiring of the OPC-ed layout images comprises generating a database (DB) including the OPC-ed layout images, and
wherein the mask layout correction method further comprises, after the correcting of the OPC-ed layout images:
generating a new DB including the corrected OPC-ed layout images;
performing mask rule check (MRC) on the corrected OPC-ed layout images;
determining that there is not a defect in the performing of the MRC; and
determining the corrected OPC-ed layout images to be final OPC-ed layout images.

6. The mask layout correction method of claim 5, wherein the performing of the MRC is a second performing of the MRC, the method comprising determining that there is a defect in a first performing of the MRC, the method further comprising performing adjustment of an interval and a width of patterns in the corrected OPC-ed layout images, proceeded by the generating of the new DB.

7. The mask layout correction method of claim 1, wherein the OPC-ed layout images are used as E-beam data for manufacturing the masks, and
wherein the E-beam data is updated or adjusted based on the correction of the OPC-ed layout images.

8. The mask layout correction method of claim 1, wherein the generating of the conversion model comprises performing a cycle generative adversarial network (GAN) algorithm with pairs of each of the OPC-ed layout images and each of corresponding mask contour images.

9. The mask layout correction method of claim 1, wherein the corrected OPC-ed layout images indicate a mask critical dimension (CD) offset in horizontal and vertical directions and an error occurring in the curvilinear pattern.

10. A mask layout correction method, comprising:
generating a database (DB) including optical proximity correction (OPC)-ed layout images for masks, each of the masks including a curvilinear pattern;
extracting mask contour images from scanning electron microscope (SEM) images for masks manufactured based on the OPC-ed layout images;
performing deep learning based on a generative adversarial network (GAN) using the OPC-ed layout images and the mask contour images to generate a conversion model;
correcting the OPC-ed layout images using the conversion model;
generating a new DB including the corrected OPC-ed layout images;
performing mask rule check (MRC) on the corrected OPC-ed layout images;
determining that there is not a defect in the performing of the MRC; and
determining the corrected OPC-ed layout images to be final OPC-ed layout images.

11. The mask layout correction method of claim 10, wherein the conversion model includes a predictive model configured to convert the OPC-ed layout image into a corresponding mask contour image and a reverse model configured to convert the mask contour image into a corresponding OPC-ed layout image, and
wherein, in the correcting of the OPC-ed layout images, the OPC-ed layout images are corrected using the reverse model.

12. The mask layout correction method of claim 11, wherein, in the correcting of the OPC-ed layout images, the OPC-ed layout images are corrected into OPC-ed layout images corresponding to mask contour images of a target using the reverse model.

13. The mask layout correction method of claim 10, wherein the performing of the MRC is a second performing of the MRC, the method further comprising determining that there is a defect in a first performing of the MRC, wherein, when the defect is determined, an interval and a width of patterns in the corrected OPC-ed layout images are adjusted so that the MRC is satisfied, and the method proceeds to the generating of a new DB.

14. The mask layout correction method of claim 10, wherein the generating of a conversion model comprises performing a cycle GAN algorithm with pairs of each of the OPC-ed layout images and each of corresponding mask contour images.

15. A mask manufacturing method comprising:
generating a database (DB) including optical proximity correction (OPC)-ed layout images for masks, the masks including a curvilinear pattern;
extracting mask contour images from scanning electron microscope (SEM) images for masks manufactured based on the OPC-ed layout images;
performing deep learning based on a generative adversarial network (GAN) using the OPC-ed layout images and the mask contour images to generate a conversion model;
correcting the OPC-ed layout images using the conversion model to acquire final OPC-ed layout images;
transferring the final OPC-ed layout images as mask tape-out (MTO) design data;
preparing mask data based on the MTO design data; and
exposing a substrate for a mask based on the mask data.

16. The mask manufacturing method of claim 15, wherein the conversion model includes a predictive model configured to convert the OPC-ed layout image into a corresponding mask contour image and a reverse model configured to convert the mask contour image into a corresponding OPC-ed layout image,
wherein, in the correcting of the OPC-ed layout images, the OPC-ed layout images are corrected to OPC-ed layout images corresponding to mask contour images of a target using the reverse model.

17. The mask manufacturing method of claim 15, wherein the acquiring of a final OPC-ed layout image includes:
generating a new database (DB) including the corrected OPC-ed layout images;
performing mask rule check (MRC) on the corrected OPC-ed layout images;
determining that there is not a defect in performing the MRC; and
determining the corrected OPC-ed layout images to be final OPC-ed layout images.

18. The mask manufacturing method of claim 17, wherein the performing of the MRC is a second performing of the MRC, the method further comprising determining that there is a defect in a first performing of the MRC and adjusting an interval and a width of patterns in the corrected OPC-ed layout images so that the MRC is satisfied, and followed by the generating of the new DB.

19. The mask manufacturing method of claim 15, wherein the mask data includes E-beam data,
wherein E-beam writing is performed using the E-beam data in the exposing operation, and
wherein the E-beam data is updated or adjusted based on the corrected OPC-ed layout images.

20. The mask manufacturing method of claim 15, wherein, the generating of the conversion model comprises performing a cycle GAN algorithm with pairs of each of the OPC-ed layout images and each of corresponding mask contour images.
